(19) United States
(12) Patent Application Publication
(10) Pub. No.: US 2023/0200150 A1
(43) Pub. Date: Jun. 22, 2023

(54) DISPLAY PANEL

(71) Applicant: Shenzhen China Star Optoelectronics Semiconductor Display Technology Co., Ltd., Shenzhen, Guangdong (CN)

(72) Inventor: Chuanbao LUO, Shenzhen, Guangdong (CN)

(21) Appl. No.: 17/624,019

(22) PCT Filed: Dec. 22, 2021
(86) PCT No.: PCT/CN2021/140579

§ 371 Date: Dec. 30, 2021

(51) Int. Cl. H01L 27/32

(52) U.S. Cl. CPC H01L 27/3272

(57) ABSTRACT

A display panel includes a first thin-film transistor and a second thin-film transistor. The first thin-film transistor includes a first source, a first drain, a first active layer, and a first gate. The second thin-film transistor includes a second source, a second drain, a second active layer, and a second gate. The first drain of the first thin-film transistor is electrically connected to the second gate of the second thin-film transistor. An electron mobility of the first active layer of the first thin-film transistor is greater than or equal to an electron mobility of the second active layer of the second thin-film transistor. A threshold voltage offset of the second active layer of the second thin-film transistor is less than or equal to a threshold voltage offset of the first active layer of the first thin-film transistor.

### FIELD OF INVENTION

The present invention is related to the field of display technology and specifically to a display panel that can be applied to large-sized display devices and has dual thin-film transistors.

### BACKGROUND OF INVENTION

Low-temperature polycrystalline silicon (LTPS) thin-film transistors are widely used in display panels of small-sized display devices such as smart phones and tablet computers, due to having driving properties such as a high electron mobility and a short response time. However, since a leakage current of a low-temperature polycrystalline silicon thin-film transistor is relatively large, a display panel is set to a high refresh rate to prevent an image delay on the display panel which affects a switching of a display screen, causing a charging time of the low-temperature polycrystalline silicon thin-film transistor to be shorter.

In addition, thin-film transistors adopting metal oxides such as indium gallium zinc oxide (IGZO) have a lower leakage current and a higher stability, and therefore can be configured to reduce the refresh rate of the display panel. However, an electron mobility of an indium gallium zinc oxide thin-film transistor is lower than an electron mobility of the low-temperature polycrystalline silicon thin-film transistor, and therefore the indium gallium zinc oxide thin-film transistor requires a higher driving voltage.

In order to make full use of the high electron mobility of the low-temperature polycrystalline silicon thin-film transistor and the low leakage current properties of the indium gallium zinc oxide thin-film transistor, in the prior art, a display panel combining the low-temperature polycrystalline silicon thin-film transistor and the indium gallium zinc oxide thin-film transistor, i.e., a low-temperature polycrystalline oxide (LTPO) display panel is designed.

The low-temperature polycrystalline silicon thin-film transistor requires a certain proportion of hydrogen (H) atoms to passivate a P-type silicon (P—Si) semiconductor and dangling bonds at an interface between the P—Si semiconductor and the N-type silicon (N—Si) semiconductor, so as to reduce defects of the P—Si semiconductor and the interface between the P—Si semiconductor and the N—Si semiconductor. For the indium gallium zinc oxide thin-film transistor, a high proportion of hydrogen atoms destroys oxygen (O) atom vacancies in the indium gallium zinc oxide and a balance of chemical bonds between metal atoms and oxygen atoms (Metal-O), causing a threshold voltage offset (Vₜₕ) of the indium gallium zinc oxide thin-film transistor to shift negatively. Therefore, the low-temperature polycrystalline silicon thin-film transistor and the indium gallium zinc oxide thin-film transistor have low compatibility to each other and are difficult to manufacture.

A manufacturing process of the low-temperature polycrystalline silicon oxide display panel is complicated, and a manufacturing process of the low-temperature polycrystalline silicon thin-film transistor is required to be performed separately from the manufacturing process of the indium gallium zinc oxide thin-film transistor. Although in the prior art, a process can be adjusted, so that the low-temperature polycrystalline silicon thin-film transistor and the indium gallium zinc oxide thin-film transistor can be smoothly combined, when the low-temperature polycrystalline silicon thin-film transistor is adopted in a manufacturing process of a large-sized display device, a crystalline uniformity of the low-temperature polycrystalline silicon is relatively poor, which affects the electron mobility and the threshold voltage offset of the low-temperature polycrystalline silicon thin-film transistor. Moreover, for the compatibility of the low-temperature polycrystalline silicon thin-film transistor and the indium gallium zinc oxide thin-film transistor to each other, applying the low-temperature polycrystalline silicon oxide display panel to the large-sized display device is difficult. Therefore, currently, the low-temperature polycrystalline silicon oxide display panel can only be applied to the small-sized display devices such as smart watches and smart bracelets.

Since the low-temperature polycrystalline silicon oxide display panel in the prior art has a technical problem of being unable to be applied to the large-sized display device, a display panel that can be applied to the large-sized display device and has dual thin-film transistors is required to solve the above-mentioned technical problems.

### SUMMARY OF INVENTION

An embodiment of the present invention provides a display panel that can be applied to large-sized display devices and has dual thin-film transistors. The display panel includes a first thin-film transistor and a second thin-film transistor. The first thin-film transistor includes a first source, a first drain, a first active layer, and a first gate. The second thin-film transistor includes a second source, a second drain, a second active layer, and a second gate. The first drain of the first thin-film transistor is electrically connected to the second gate of the second thin-film transistor. An electron mobility of the first active layer of the first thin-film transistor is greater than or equal to an electron mobility of the second active layer of the second thin-film transistor. A threshold voltage offset of the second active layer of the second thin-film transistor is less than or equal to a threshold voltage offset of the first active layer of the-first thin-film transistor.

In this embodiment, the electron mobility of the first active layer of the first thin-film transistor is 1.5 times or more of the electron mobility of the second active layer of the second thin-film transistor.

In this embodiment, the electron mobility of the first active layer of the first thin-film transistor is greater than or equal to 20 m²/(V·s).

In this embodiment, the threshold voltage offset of the second active layer of the second thin-film transistor is less than or equal to 1 V.

In this embodiment, a material of the first active layer of the first thin-film transistor includes one or more of indium oxide, gallium oxide, zinc oxide, tin oxide, and combinations thereof.

In this embodiment, a material of the second active layer of the second thin-film transistor includes metal oxide doped with rare-earth metal element or fluorine-based compound.

In another embodiment, the first thin-film transistor further includes a third active layer, the third active layer and the first active layer are laminated, and non-channel regions on two ends of the third active layer are respectfully electrically connected to non-channel regions on two ends of the first active layer.

In this embodiment, an average electron mobility of the first active layer and the third active layer of the first thin-film transistor is greater than or equal to the electron mobility of the second active layer of the second thin-film transistor.

In this embodiment, the average electron mobility of the first active layer and the third active layer of the first thin-film transistor is 1.5 times or more of the electron mobility of the second active layer of the second thin-film transistor.

In this embodiment, the average electron mobility of the first active layer and the third active layer of the first thin-film transistor is greater than or equal to 20 m²/(V·s).

In this embodiment, the material of the first active layer of the first thin-film transistor is same as the material of the second active layer of the second thin-film transistor.

In this embodiment, the first active layer of the first thin-film transistor and the second active layer of the second thin-film transistor are provided through a same manufacturing process.

In this embodiment, a material of the third active layer of the first thin-film transistor includes one or more of indium oxide, gallium oxide, zinc oxide, tin oxide, and combinations thereof.

In this embodiment, the material of the first active layer of the first thin-film transistor is different from the material of the third active layer of the first thin-film transistor.

In another embodiment, the display panel further includes a data line, a scan line, and a light-emitting unit. The data line is electrically connected to the first source of the first thin-film transistor. The scan line is electrically connected to the first gate of the first thin-film transistor. The light-emitting unit includes a first electrode and a second electrode opposite to the first electrode. The first electrode is electrically connected to the second source of the second thin-film transistor.

In this embodiment, the display panel further includes a capacitor. The capacitor includes a first plate and a second plate opposite to the first plate. The first plate is electrically connected to the drain of the first thin-film transistor and the gate of second thin-film transistor. The second plate is electrically connected to the second source of the second thin-film transistor and the light-emitting unit.

In another embodiment, the display panel further includes a light-shielding layer disposed under the second thin-film transistor.

The present invention provides a display panel that can be applied to the large-sized display devices, and includes the first thin-film transistor and the second thin-film transistor. The first thin-film transistor includes the first source, the first drain, the first active layer, and the first gate. The second thin-film transistor includes the second source, the second drain, the second active layer, and the second gate. The first drain of the first thin-film transistor is electrically connected to the second gate of the second thin-film transistor. The electron mobility of the first active layer of the first thin-film transistor is greater than or equal to the electron mobility of the second active layer of the second thin-film transistor. The threshold voltage offset of the second active layer of the second thin-film transistor is less than or equal to the threshold voltage offset of the first active layer of the first thin-film transistor. Furthermore, the first thin-film transistor further includes the third active layer. The third active layer and the first active layer are laminated so that the average electron mobility of the first active layer and the third active layer of the first thin-film transistor is greater than or equal to the electron mobility of the second active layer of the second thin-film transistor. Through a structure design of the dual thin-film transistors of the display panel and a structure design of dual active layers of the first thin-film transistor, in the present invention, the first thin-film transistor can serve as a switching thin-film transistor with a short response time, and the second thin-film transistor can serve as a driving transistor with a high stability. In addition, the first thin-film transistor with the dual active layers can increase a manufacturing yield, thereby solving the problem that the low-temperature polycrystalline silicon oxide display panel in the prior art being unable to be applied to the large-sized display devices.

### DESCRIPTION OF DRAWINGS

FIG. 1 is a circuit structural diagram of a display panel of the present invention.

FIG. 2 is a structural schematic diagram of the display panel according to a first embodiment of the present invention.

FIG. 3 is a structural schematic diagram of the display panel according to a second embodiment of the present invention.

### DETAILED DESCRIPTION OF EMBODIMENTS

In order to make above purposes, features, and advantages of the present invention more obvious and understandable, the following is a detailed description of preferred embodiments of the present invention in conjunction with accompanying drawings.

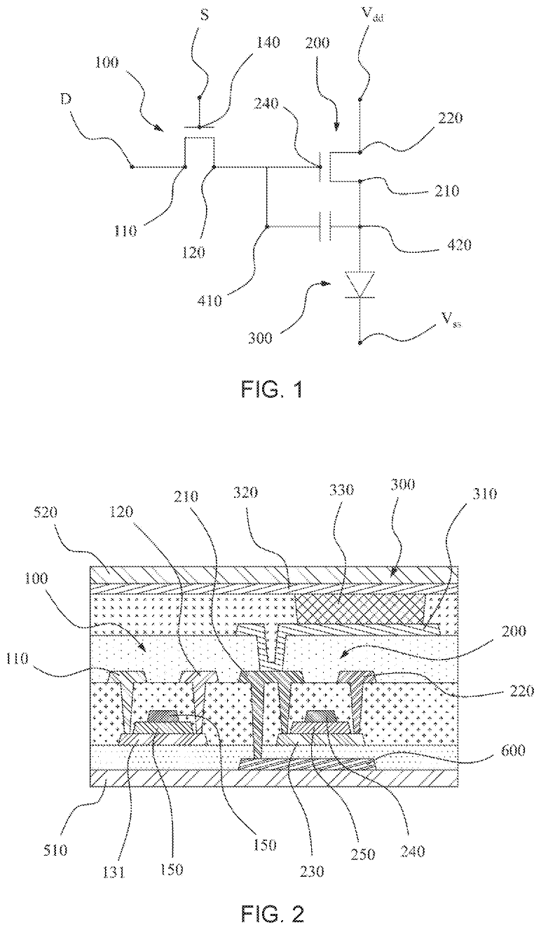

Referring to FIG. 1, which is a circuit structural diagram of a display panel of the present invention. The display panel of the present invention includes a first thin-film transistor 100 and a second thin-film transistor 200. The first thin-film transistor 100 includes a first source 110, a first drain 120, a first active layer (not shown), and a first gate 140. The second thin-film transistor 200 includes a second source 210, a second drain 220, a second active layer (not shown), and a second gate 240.

As shown in FIG. 1, the display panel further includes a data line D, a scan line S, and a light-emitting unit 300. The data line D is electrically connected to the first source 110 of the first thin-film transistor 100. The scan line S is electrically connected to the first gate 140 of the first thin-film transistor 100. The first thin-film transistor 100 is configured to receive display signals transmitted by the data line D and the scan line S of the display panel. Through controlling an input voltage of the first gate 140, the first thin-film transistor 100 can control on and off of the current on two ends of the first source 110 and the first drain 120.

In addition, as shown in FIG. 1, the display panel further includes a common anode V_{dd} and a common cathode Vₛₛ. The common anode V_{dd} is electrically connected to the second drain 220 of the second thin-film transistor 200. The first drain 120 of the first thin-film transistor 100 is electrically connected to the second gate 240 of the second thin-film transistor 200. Two ends of the light-emitting unit 300 are electrically connected to the second source 210 of the second thin-film transistor 200 and the common cathode Vₛₛ. The second thin-film transistor 200 is configured to receive switching signals of the first drain 120 of the first thin-film transistor 100. Through controlling an input voltage of the second gate 240, the second thin-film transistor 200 can control on and off of the current on two ends of the second source 210 and the second drain 220. When a current of the common anode V_{dd} is inputted to the light-emitting unit 300 through the second thin-film transistor 200, the light-emitting unit 300 can emit light, so that the display panel can display images.

It can be seen from this that among the first thin-film transistor 100 and the second thin-film transistor 200, the first thin-film transistor 100 serves as a switching thin-film transistor that turns on or off the second thin-film transistor, and the second thin-film transistor 200 serves as a driving thin-film transistor that drives the light-emitting unit 300.

In an embodiment, as shown in FIG. 1, the display panel further includes a capacitor 400. The capacitor 400 includes a first plate 410 and a second plate 420 opposite to the first plate 410. The first plate 410 is electrically connected to the first drain 120 of the first thin-film transistor 100 and the second gate 240 of the second thin-film transistor 200. The second plate 420 is electrically connected to the second source 210 of the second thin-film transistor 200 and the light-emitting unit 300. The capacitor is configured to store the switching signals inputted by the first thin-film transistor 100 and convert the switching signals into current signals required for the light-emitting unit 300 to emit light, so as to display different grayscale values.

In actual implementations, the light-emitting unit 300 includes an organic light-emitting diode (OLED), a mini-light-emitting diode (mini-LED), and a micro-light-emitting diode (micro-light-emitting diode, Micro-LED), electroluminescent quantum dots (ELQDs), etc.

### First Embodiment

Referring to FIG. 2, which is a structural schematic diagram of the display panel according to a first embodiment of the present invention.

In this embodiment, the display panel includes a lower substrate 510 and an upper substrate 520 to protect all components in the display panel. The lower substrate 510 and the upper substrate 520 include, but are not limited to, glass substrates, polyimide substrates, etc., which can be rigid substrates or flexible substrates.

The display panel of this embodiment includes the first thin-film transistor 100 and the second thin-film transistor 200. The first thin-film transistor 100 includes the first active layer 131, the first gate insulating layer 150, and the first gate 140 laminated in sequence, and further includes the first source 110 and the first drain 120 electrically connected to two ends of the first active layer 131. The second thin-film transistor 200 includes the second active layer 230, the second gate insulating layer 250, and the second gate 240 laminated in sequence, and further includes the second source 210 and the second drain 220 electrically connected to two ends of the second active layer 230.

In this embodiment, the first thin-film transistor 100 and the second thin-film transistor 200 include top-gate thin-film transistors. With an advancement of manufacturing processes, the top-gate thin-film transistor can reduce a manufacturing process of the display panel, thereby reducing manufacturing costs of the display panel.

The display panel in this embodiment further includes the light-emitting unit 300. In this embodiment, the light-emitting unit 300 being an organic light-emitting diode is taken as an example. The light-emitting unit 300 includes a first electrode 310, a second electrode 320 opposite to the first electrode 310, and a light-emitting layer 330. The first electrode 310 is electrically connected to the second source 210 of the second thin-film transistor 200. When the second thin-film transistor 200 controls the current to be conducted to the light-emitting unit 300, the current flows between the first electrode 310 serving as an anode and the second electrode 320 serving as a cathode. Under an action of the current, electrons and holes in the light-emitting unit 300 are combined in the light-emitting layer 330 and excite light, thereby achieving an image display of the display panel.

In this embodiment, the first thin-film transistor 100 serves as a switching thin-film transistor with a short response time, and the second thin-film transistor 200 serves as the driving transistor with a high stability. Therefore, the first active layer 131 of the first thin-film transistor 100 is made of materials having a high electron mobility, and a material of the second active layer 230 of the second thin-film transistor 200 is made of materials with a low leakage current. In other words, the electron mobility of the first active layer 131 of the first thin-film transistor 100 of this embodiment is greater than or equal to an electron mobility of the second active layer 230 of the second thin-film transistor 200. A threshold voltage offset of the second active layer 230 of the second thin-film transistor 200 is less than or equal to a threshold voltage offset of the first active layer 131 of the first thin-film transistor 100.

In this embodiment, a material of the first active layer 131 of the first thin-film transistor 100 includes, but is not limited to, indium oxide, gallium oxide, zinc oxide, tin oxide, and combinations thereof. Preferably, the material of the first active layer 131 can be materials having a high electron mobility, such as indium gallium zinc oxide (IGZO), indium gallium zinc tin oxide (IGZTO), indium zinc tin oxide (IZTO), etc. Through experiments of the inventor, the electron mobility of the first active layer 131 of the first thin-film transistor 100 is at least greater than or equal to 20 m²/(V·s). In this embodiment, the electron mobility of the first active layer 131 of the first thin-film transistor 100 can reach to 1.5 times or more of the electron mobility of the second active layer 230 of the second thin-film transistor 200.

The greater the electron mobility, the shorter the response time of the first thin-film transistor 100, so that the first thin-film transistor 100 serving as the switching thin-film transistor has excellent technical advantages.

In this embodiment, the material of the second active layer 230 of the second thin-film transistor 200 includes, but is not limited to, metal oxide doped with rare-earth metal element or fluorine-based compound. Preferably, the material of the second active layer 230 can be metal oxide doped with lanthanide series of chemical elements, such as praseodymium (Pr), cerium (Ce), or lanthanum (La), metal oxide doped with fluoride series of compounds such as nitrogen trifluoride (NF₃), carbon tetrafluoride (CF₄), or sulfur hexafluoride (SF₆) metal oxides, or other materials with a low leakage current. The metal oxide can be metal oxide with low indium content. Through experiments of the inventor, the threshold voltage offset of the second active layer 230 of the second thin-film transistor 200 is less than or equal to 1 V. The smaller the threshold voltage offset, the higher the stability of the second thin-film transistor 200, so that the second thin-film transistor 200 serving as the driving thin-film transistor has excellent technical advantages.

In addition, in this embodiment, in order to further increase the stability of the second thin-film transistor 200, the display panel further includes a light-shielding layer 600. Since the material properties of the second active layer 230 are easily affected by light, the light-shielding layer 600 is disposed under the second thin-film transistor 200 in this embodiment, so as to shield light that irradiates on the second active layer 230 of the second thin-film transistor 200, and maintain the high stability that the second thin-film transistor 200 is required to have. In addition, the light-shielding layer 600 can also serve as a wiring of the second source 210 of the second thin-film transistor 200, so that a structure of the display panel is simplified.

### Second Embodiment

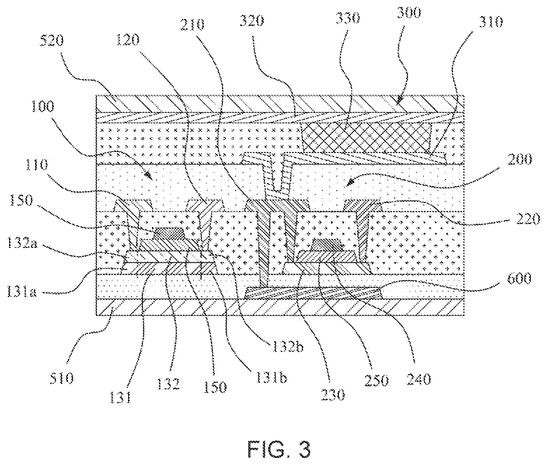

Referring to FIG. 3, which is a structural schematic diagram of the display panel according to a second embodiment of the present invention.

In this embodiment, for main structures of the display panel, for example, material properties, relative positions, and connection relations of the lower substrate 510, the upper substrate 520, the first source 110, the first source 100 and the first drain 120 of the first thin-film transistor 100, the second source 210 and the second drain 220 of the second thin-film transistor 200, the light-shielding layer 600, and the light-emitting unit 300 are all same. In addition, preferably, the first thin-film transistor 100 and the second thin-film transistor 200 are also top-gate thin-film transistors to reduce the manufacturing process of the display panel, thereby reducing the manufacturing costs of the display panel.

However, a difference between this embodiment and the first embodiment is that the first thin-film transistor 100 further includes a third active layer. The third active layer and the first active layer 131 are laminated and the third active layer is disposed on the first active layer 131. Non-channel regions 132a and 132b on two ends of the third active layer are respectively electrically connected to non-channel regions 131a and 131b on two ends of the first active layer 131. In this embodiment, the non-channel region 132a of the third active layer and the non-channel region 131a of the first active layer 131 are conductorized, and the non-channel region 132b of the third active layer and the non-channel region 131b of the first active layer 131 are conductorized. Therefore, in the first thin-film transistor 100, the first source 110 can be electrically connected to the third active layer and the first active layer 131 simultaneously through the non-channel region 132a of the third active layer and the non-channel region 131a of the first active layer 131 that are conductorized, and the first drain 120 can be electrically connected to the third active layer and the first active layer 131 simultaneously through the non-channel region 132b of the third active layer and the non-channel region 131b of the first active layer 131 that are conductorized.

Similar to the first embodiment of the present invention, the first thin-film transistor 100 serves as the switching thin-film transistor with the short response time in this embodiment, and the second thin-film transistor 200 serves as the driving transistor with the high stability. Therefore, the third active layer of the first thin-film transistor 100 is made of materials having a high electron mobility, and the material of the second active layer 230 of the second thin-film transistor 200 is made of materials with a low leakage current. In other words, an average electron mobility of the first active layer 131 and the third active layer of the first thin-film transistor 100 of this embodiment is greater than or equal to the electron mobility of the second active layer 230 of the second thin-film transistor 200. The threshold voltage offset of the second active layer 230 of the second thin-film transistor 200 is less than or equal to that an average threshold voltage offset of the first active layer 131 and the third active layer of the first thin-film transistor 100.

In this embodiment, in order to further increase the average electron mobility of the first active layer 131 and the third active layer of the first thin-film transistor 100, a material of the third active layer of the first thin-film transistor 100 includes, but are not limited to, indium oxide, gallium oxide, zinc oxide, tin oxide, and combinations thereof. Preferably, the material of the first active layer 131 and the material of the third active layer can respectively be the material having high electron mobility, such as the indium gallium zinc oxide and indium tin oxide, or indium gallium zinc oxide and indium gallium tin oxide. Through experiments of the inventor, the average electron mobility of the first active layer 131 and the third active layer of the first thin-film transistor 100 is at least greater than or equal to 20 m²/(V·s), or even two to three times greater than the electron mobility of the first active layer 131 of the first thin-film transistor 100 of the first embodiment. The greater the electron mobility, the shorter the response time of the first thin-film transistor 100, so that the first thin-film transistor 100 serving as the switching thin-film transistor has excellent technical advantages.

It should be noted that, in the first thin-film transistor 100, the material of the first active layer 131 described in the above embodiment is different from the material of the third active layer. However, “different” in this embodiment refer to a difference in material compositions, basic materials of the first active layer 131 and basic materials of the third active layer can be the same, and the material of the first active layer 131 and the material of the third active layer that are different from each other can be formed through doping with different proportions of metal elements.

In this embodiment, in order to simplify the manufacturing process of the display panel, the material of the first active layer 131 of the first thin-film transistor 100 can be formulated to be same as the material of the active layer 230 of the second thin-film transistor 200. Therefore, the first active layer 131 of the first thin-film transistor 100 can be formed simultaneously with the second active layer 230 of the second thin-film transistor 200 in a same manufacturing process, thereby simplifying the manufacturing process of the display panel and enhance a production efficiency.

In this embodiment, since the material and the material properties of the second active layer 230 of the second thin-film transistor 200 are same as the material and the material properties described in the first embodiment, the details are not reiterated herein.

The present invention provides a display panel that can be applied to the large-sized display devices, and includes the first thin-film transistor 100 and the second thin-film transistor 200. The first thin-film transistor 100 includes the first source 110, the first drain 120, the first active layer 131, and the first gate 140. The second thin-film transistor 200 includes the second source 210, the second drain 220, the second active layer 230, and the second gate 240. The first drain 120 of the first thin-film transistor 100 is electrically connected to the second gate 240 of the second thin-film transistor 200. The electron mobility of the first active layer 131 of the first thin-film transistor 100 is greater than or equal to the electron mobility of the second active layer 230 of the second thin-film transistor 200. The threshold voltage offset of the second active layer 230 of the second thin-film transistor 200 is less than or equal to the threshold voltage offset of the first active layer 131 of the first thin-film transistor 100. Furthermore, the first thin-film transistor 100 further includes the third active layer. The third active layer and the first active layer 131 are laminated so that the average electron mobility of the first active layer 131 and the third active layer of the first thin-film transistor 100 is greater than or equal to the electron mobility of the second active layer 230 of the second thin-film transistor 200. Through a structure design of the dual thin-film transistors of the display panel and a structure design of dual active layers of the first thin-film transistor 100, in the present invention, the first thin-film transistor 100 can serve as the switching thin-film transistor with the short response time, and the second thin-film transistor can serve as the driving transistor with the high stability. In addition, the first thin-film transistor with the dual active layers can increase a manufacturing yield, thereby solving the problem that a low-temperature polycrystalline silicon oxide display panel in the prior art being unable to be applied to the large-sized display devices.

The descriptions above are only preferred embodiments of the invention. It should be pointed out that to those of ordinary skill in the art, various improvements and embellishments may be made without departing from the principle of the present invention, and these improvements and embellishments are also deemed to be within the scope of protection of the present invention.

What is claimed is:

1. A display panel, comprising:
a first thin-film transistor comprising a first source, a first drain, a first active layer, and a first gate; and
a second thin-film transistor comprising a second source, a second drain, a second active layer, and a second gate;
wherein the first drain of the first thin-film transistor is electrically connected to the second gate of the second thin-film transistor, an electron mobility of the first active layer of the first thin-film transistor is greater than or equal to an electron mobility of the second active layer of the second thin-film transistor, and a threshold voltage offset of the second active layer of the second thin-film transistor is less than or equal to a threshold voltage offset of the first active layer of the-first thin-film transistor.

2. The display panel according to claim 1, wherein the electron mobility of the first active layer of the first thin-film transistor is 1.5 times or more of the electron mobility of the second active layer of the second thin-film transistor.

3. The display panel according to claim 1, wherein the electron mobility of the first active layer of the first thin-film transistor is greater than or equal to 20 m²/(V·s).

4. The display panel according to claim 1, wherein the threshold voltage offset of the second active layer of the second thin-film transistor is less than or equal to 1 V.

5. The display panel according to claim 1, wherein a material of the first active layer of the first thin-film transistor comprises one or more of indium oxide, gallium oxide, zinc oxide, tin oxide, and combinations thereof.

6. The display panel according to claim 1, wherein a material of the second active layer of the second thin-film transistor comprises metal oxide doped with rare-earth metal element or fluorine-based compound.

7. The display panel according to claim 1, further comprising:
a data line electrically connected to the first source of the first thin-film transistor;
a scan line electrically connected to the first gate of the first thin-film transistor; and
a light-emitting unit comprising a first electrode and a second electrode opposite to the first electrode, wherein the first electrode is electrically connected to the second source of the second thin-film transistor.

8. The display panel according to claim 7, further comprising:
a capacitor comprising a first plate and a second plate opposite to the first plate, wherein the first plate is electrically connected to the drain of the first thin-film transistor and the gate of second thin-film transistor, and the second plate is electrically connected to the second source of the second thin-film transistor and the light-emitting unit.

9. The display panel according to claim 1, further comprising:
a light-shielding layer disposed under the second thin-film transistor.

10. The display panel according to claim 1, wherein the first thin-film transistor further comprises a third active layer, the third active layer and the first active layer are laminated, and non-channel regions on two ends of the third active layer are respectfully electrically connected to non-channel regions on two ends of the first active layer.

11. The display panel according to claim 10, wherein an average electron mobility of the first active layer and the third active layer of the first thin-film transistor is greater than or equal to the electron mobility of the second active layer of the second thin-film transistor.

12. The display panel according to claim 11, wherein the average electron mobility of the first active layer and the third active layer of the first thin-film transistor is 1.5 times or more of the electron mobility of the second active layer of the second thin-film transistor.

13. The display panel according to claim 11, wherein the average electron mobility of the first active layer and the third active layer of the first thin-film transistor is greater than or equal to 20 m²/(V·s).

14. The display panel according to claim 10, wherein a material of the first active layer of the first thin-film transistor is same as a material of the second active layer of the second thin-film transistor.

15. The display panel according to claim 10, wherein the first active layer of the first thin-film transistor and the second active layer of the second thin-film transistor are provided through a same manufacturing process.

16. The display panel according to claim 10, wherein a material of the third active layer of the first thin-film transistor comprises one or more of indium oxide, gallium oxide, zinc oxide, tin oxide, and combinations thereof.

17. The display panel according to claim 16, wherein a material of the first active layer of the first thin-film transistor is different from the material of the third active layer of the first thin-film transistor.

18. The display panel according to claim 10, further comprising:
a data line electrically connected to the first source of the first thin-film transistor;
a scan line electrically connected to the first gate of the first thin-film transistor; and
a light-emitting unit comprising a first electrode and a second electrode opposite to the first electrode, wherein the first electrode is electrically connected to the second source of the second thin-film transistor.

19. The display panel according to claim 18, further comprising:
a capacitor comprising a first plate and a second plate opposite to the first plate, wherein the first plate is electrically connected to the drain of the first thin-film transistor and the gate of second thin-film transistor, and the second plate is electrically connected to the second source of the second thin-film transistor and the light-emitting unit.

20. The display panel according to claim 10, further comprising:
a light-shielding layer disposed under the second thin-film transistor.
